(19) United States
(12) Patent Application Publication
(10) Pub. No.: US 2010/0014631 A1
(43) Pub. Date: Jan. 21, 2010

(54) SCINTILLATOR BASED X-RAY SENSITIVE INTEGRATED CIRCUIT ELEMENT WITH DEPLETED ELECTRON DRIFT REGION

(75) Inventors: Jan Sonsky, Leuven (BE); Matthias Simon, Aachen (DE)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V., Eindhoven (NL)

(21) Appl. No.: 12/438,157

(22) PCT Filed: Sep. 6, 2007
(86) PCT No.: PCT/IB07/53597

§ 371 Date: Feb. 20, 2009

(30) Foreign Application Priority Data
Sep. 14, 2006 (EP) 06120673.6

(51) Int. Cl. H05G 1/60; H01L 31/0232; G01T 1/20

(52) U.S. Cl. 378/19; 257/432; 438/69; 250/361 R; 257/E31.129

(57) ABSTRACT

It is described an integrated circuit design and a method to fabricate the same for a high-efficiency, low-noise, position sensitive X-ray detection in particular for medical applications. The device (350) is based on deep recesses (354) filled with an X-ray sensitive scintillator material. A shallow first electrode (360) is formed on the surface of the substrate (352) sidewalls separating two neighboring recesses (354). This sidewall electrode (360) in combination with particular frontside wafer electrode (363) structure results in a full depletion of the entire device (350) and a removal of signal charge towards the low capacitance readout electrode (363). The described integrated circuit element (350) ensures high and not depth dependent light collection efficiency.

### FIELD OF INVENTION

The present invention generally relates to the field of detecting X-ray photons by means of an X-ray sensitive imaging detection system. Specifically, the present invention relates to a scintillator based X-ray sensitive integrated circuit element, which may be used for an X-ray imaging detector, in particular for a spatially resolving X-ray imaging detector for medical applications.

Further, the present invention relates to an X-ray imaging detector comprising a plurality of X-ray sensitive integrated circuit elements as described above.

Furthermore, the present invention relates to an X-ray imaging apparatus being used in particular for medical X-ray imaging, whereby the X-ray imaging apparatus comprises an X-ray imaging detector as described above.

The present invention further relates to a method for fabricating a scintillator based X-ray sensitive integrated circuit element as described above.

### ART BACKGROUND

Medical X-ray imaging requires large area, low noise and position-sensitive respectively spatially resolving X-ray detection systems, which may be manufactured at a competitive prize. Currently commercially available X-ray detection systems are based on a combination of scintillator and a pixel photodiode array based on amorphous Silicon (Si). The scintillator converts the X-rays into light photons with a high efficiency and these light photons are subsequently absorbed in the photodiodes, wherein they are converted into electrical charge carriers. The charge carriers generate a signal at an electrode representing a readout node of the X-ray detection system. Each pixel of a typically Si photodiode is accompanied with a storage capacitor and a thin film transistor (TFT) for pixel addressing.

The combination of scintillator and amorphous Si photodiodes allows efficient X-ray absorption with the scintillator material combined with a comparatively high light sensitivity and a low dark current of amorphous Si photodiodes. The system has reasonably low overall noise, whereby switching elements, amplifier and TFT-related components being the major noise contributors. The currently available X-ray detection systems have a size of approximately 40 cm×40 cm with a pixel size of around 150 μm×150 μm.

U.S. Pat. No. 6,744,052 discloses a method and a device for producing an X-ray sensitive pixel detector. The detector comprises a structure based on light-guiding of secondarily produced photons within a scintillating pixel detector in conjunction with a CCD or a CMOS sensor array. The structure presents a matrix having deep pores fabricated by silicon etching techniques producing very thin walls and a pore spacing less or equal to the size of a pixel of the image detector used. The pore matrix is filled by melting a scintillating material into the pores such that, in each pore, a single scintillating block is formed. The silicon matrix may further utilize a reflective layer to increase light guiding down to the image detector chip. The described X-ray sensitive pixel detector has the disadvantage, that the light output and thus overall detection efficiency is typically not satisfactory in particular for medical X-ray imaging application such as e.g. computed tomography. Thereby, the overall detection efficiency is reduced in particular due to a limited quality of the scintillator material e.g. because of light loss due to defects within the scintillator. The overall detection efficiency is further reduced because of losses during the reflection on the sidewalls e.g. due to sidewall roughness. Also secondary quantum noise plays a major role due to the depth dependence of conversion efficiency.

The publication “Formation of pn junctions in deep silicon pores for X-ray imaging detector applications, X. Badel et al., Nuclear Instruments and Methods in Physics Research A 509 (2003) 96-101” discloses a concept for an X-ray imaging detector, which concept is based on the formation of pn junctions in deep silicon pores. The sensitive part of the X-ray imaging detector is an array of CsI(Tl) scintillator columns formed by filling a silicon matrix of pores having pn junctions in their walls. Under X-ray illumination, the CsI(Tl) scintillator emits photons that are collected by the pn junctions. The pore matrices can be fabricated in n-type silicon by deep reactive ion etching or by photo-electrochemical etching. The pn junctions can be formed either by boron diffusion and/or deposition of boron doped poly-silicon.

However, even if recent developments in the field of X-ray imaging detectors have improved the noise, the spatial resolution and the quantum efficiency of X-ray sensitive detectors, there is still a need to further improve these characteristic X-ray detector properties, which are in particular relevant for medical X-ray imaging.

### SUMMARY OF THE INVENTION

This need may be met by the subject matter according to the independent claims. Advantageous embodiments of the present invention are described by the dependent claims.

According to a first aspect of the invention there is provided an X-ray sensitive integrated circuit element for an X-ray imaging detector, in particular for an X-ray imaging detector being used for medical applications. The X-ray sensitive integrated circuit element comprises (a) a semiconductor substrate having a frontside surface and a backside surface, (b) a plurality of recesses being formed within the semiconductor substrate from the backside surface towards the frontside surface, whereby two neighboring recesses are separated by a sidewall of the semiconductor substrate, (c) a plurality of first electrodes, whereby respectively one first electrode is formed at an inner surface of one recess, (d) an X-ray sensitive scintillator material being filled within the plurality of recesses, and (e) a plurality of second electrodes being formed at the frontside surface, whereby respectively one second electrode faces one sidewall.

This aspect of the invention is based on the idea that the first electrodes and the second electrodes may generate an electric field within the sidewalls, which electric field causes a full depletion of the sidewalls. In other words, when appropriately biasing the first electrodes within the semiconductor substrate and the second electrodes at the frontside surface of the semiconductor substrate, the described distribution of first and second electrodes shapes the electrical potential inside the sidewalls in such a manner, that all light generated charge may be transported toward the second electrode. Therefore, the second electrode represents a collection electrode respectively a readout node.

It has to be pointed out that the second electrodes may be made from a semiconductor layer comprising a first conductivity type and the first electrodes may be made from a semiconductor layer comprising a second conductivity type. Further, the sidewalls formed from the semiconductor substrate may comprise the first conductivity type.

Within the described integrated circuit element respectively one second electrode faces one semiconductor substrate sidewall. This means that respectively one second electrode extends in between two neighboring recesses. In order to be precise, the respectively one second electrode extends in between the projection of two neighboring recesses onto the frontside surface. This has the above-mentioned effect that in between two neighboring first electrodes and a corresponding second electrode being located in between the two first electrodes an electric field may be generated, which allows for a full depletion of the sidewalls. Thereby, the region of depletion is effectively increased such that also the volume of the charge-generating region within the X-ray sensitive integrated circuit is enhanced. This has the advantage that the collection efficiency of the X-ray sensitive integrated circuit may be enhanced because the probability is increased that photons being converted by the scintillator material generate charge carriers within the active detector region being represented by the sidewalls.

Furthermore, the second electrode representing a readout electrode can be realized with much smaller dimensions as compared the readout electrodes known in prior art. This leads to significant reduction of the capacitance, further enhanced by the comparatively much larger depletion layer thickness such that the sidewalls are fully depleted.

The conversion from X-ray photons into photons within preferably the visible spectral range is a well-know physical effect, which will not be described here in more detail. An appropriate scintillator material is e.g. Cesiumiodide (CsI) which is doped e.g. with Thallium (Tl).

It has to be mentioned that the full depletion of the sidewalls may further provide the benefiting effect that the capacitance of the integrated circuit element is reduced. Thereby, faster response times of a corresponding X-ray sensitive detector and lower noise may be achieved. This holds even if the area of the first electrodes is comparatively large.

The term recess may cover all different shapes of hollow spaces, which may be formed within the semiconductor substrate starting from the backside surface. Therefore, the term recess has to be understood in a very general way, which includes for instance the terms trench, slot, pore and/or indentation. The recesses may have the shape not only of squares. Also circular or hexagonal shapes recesses may be employed.

According to an embodiment of the invention the recesses are deep structures having a depth, which is larger than the width. Thereby, the width extends parallel to the backside surface whereas the depth of the recesses extends predominately perpendicular to the backside surface. This may provide the advantage that a large active detector volume of both the X-ray sensitive scintillator region and the light sensitive sidewall region can be realized even if the recesses are formed within close distance to each other such that a high spatial resolution may be achieved. Typical dimensions for the recesses are a cross-section oriented parallel to the frontside respectively the backside surface of approximately 50 μm×50 μm and a depth perpendicular to the frontside respectively the backside surface of approximately 500 μm.

According to a further embodiment of the invention the X-ray sensitive integrated circuit element further comprises a plurality of third electrodes being formed at the frontside surface, whereby respectively one third electrode is arranged in between two neighboring second electrodes. The third electrodes may be made from a semiconductor material respectively layer comprising the second conductivity type, which is the same type of doping as the first electrodes and the opposite type of doping as compared to the second electrodes. When connecting these electrodes to an appropriate voltage level such as ground level, this may provide the advantage that an electric potential in between two neighboring second electrodes is generated, which allows for an effective separation of the drift field associated with the second electrodes representing neighboring readout nodes of the integrated circuit element. Therefore, the third electrode may also be denoted as a guard electrode.

According to a further embodiment of the invention the first electrodes have a thickness of less than 5 μm, preferably less than 1 μm. This means that the first electrodes represent very shallow sidewall junctions such that a high light sensitivity may be achieved because only few photons will be absorbed in the boundary layer formed in between the scintillator and the active sidewall region. Further, a shallow sidewall junction may also contribute to a full depletion of free charge carriers within the sidewall volume of the semiconductor substrate.

According to a further embodiment of the invention the X-ray sensitive integrated circuit element further comprises a light-reflecting layer, which is provided at a surface of the scintillator formed at the back surface of the semiconductor substrate. This may allow for a further increased sensitivity of the integrated circuit element because light, which has been converted by the scintillator material cannot escape from the integrated circuit element.

The light reflecting layer may be for example a thin metal layer, which can be formed on the scintillator by means of known coating techniques after the recesses have been filled with the scintillator material.

According to a further embodiment of the invention the semiconductor substrate is at least a part of a semiconductor wafer, which preferably is made from Silicon. This has the advantage that a high purity base material can be provided easily. A high purity semiconductor material may allow for long recombination times of light generated charge carriers within the sidewalls predominately representing the active detector region. Thereby, the quantum yield respectively the detector efficiency will be increased because of a reduced electron loss caused by recombination processes.

Furthermore, a high purity semiconductor material having only negligible contaminations has the advantage that the mobility of the generated charge carriers will be increased. Therefore, a fast charge carrier collection respectively a fast electron drift and as a consequence a fast response time of an X-ray detector using the described integrated circuit element can be realized.

According to a further embodiment of the invention the X-ray sensitive integrated circuit element further comprises a passivation layer being formed in between the scintillator material and the first electrode. The provision of such a passivation layer has the advantage that a defined boundary between the semiconductor material and the scintillator material is realized. Therefore, there is no diffusion from atoms of the scintillator material into the semiconductor and vice versa. Preferably, the passivation layer is a very thin layer having a thickness of approximately 10 nm. The passivation layer may be for instance SiO₂. A thin passivation layer has the advantage that the absorption of light being converted by the scintillator material will not or not significantly be increased such a high detector efficiency will be retained. The thickness of the passivation layer may be optimized dependently on the wavelength of the light emitted from scintillator, so that maximum light transmission through this passivation layer is achieved.

According to a further embodiment of the invention (a) the semiconductor substrate is an intrinsic or a lowly n-type doped semiconductor material, (b) the first electrode is formed as a p-type doped region within the semiconductor, and (c) the second electrode is formed as an n-type doped region within the semiconductor. This may provide the advantage that the described integrated circuit element can be manufactured by means of standard semiconductor manufacturing techniques using in particular CMOS compatible process technology, which is well developed for a variety of different semiconductor applications. Therefore, the described integrated circuit element can be manufactured in a reliable and cost-effective manner.

Preferably, the p-type doped first electrode is connected by means of a highly p-type doped contact region within the semiconductor substrate, whereby the highly p-type doped contact region itself may be connected to outside contacts by means of connecting technologies being well known in semiconductor processing.

In particular when the semiconductor substrate is a lowly n-type doped material the second electrode may be realized by means of a highly n-type doped region. Further, if a third electrode is provided in order to separate neighboring second electrodes from each other the third electrode may preferably be formed by a highly p-type doped region.

It has to be mentioned that of course the type of doping can be interchanged in between the first and the second electrode. This means that the X-ray sensitive integrated circuit element may also be realized when the first electrode is an n-type doped region and the second electrode is a p-type doped or even a highly p-type doped region. Of course, in that case the first electrode may be connected by means of a highly n-type doped contact region. Furthermore, in case a third electrode is used in order to separate neighboring second electrodes from each other, the third electrode may preferably be formed by a highly n-type doped region.

According to a further embodiment of the invention the first electrode is contacted from the backside surface of the semiconductor substrate. As the first electrode is typically biased at the high voltage, this may provide the advantage that all high voltage connections are on the back-side, while all connections for signal readout and processing (typically low voltage signals) are provided on the front-side.

According to a further embodiment of the invention the first electrode in contacted from the frontside surface of the semiconductor substrate. This alternative embodiment is in particular attractive because all connections may be located on the same side of the semiconductor substrate, such that a processing of the integrated circuit element can be realized by means of standard CMOS compatible processing technology. Thereby, a crystalline silicon wafer may be used as the semiconductor substrate.

A conductive path formed in between the first electrode and the frontside surface may be realized by means of poly silicon, which may be doped in an appropriate manner in order to provide for a sufficient conductivity. This has the advantage that the thermal expansion coefficient of a substrate being made from a Silicon crystal and the thermal expansion coefficient of poly silicon is quite similar such that the thermal stability of the integrated circuit element may be increased.

According to a further embodiment of the invention the first electrode is segmented in depth. This means that the first electrode comprises a plurality of small electrode elements, which are not connected with each other. However, in case neighboring electrode elements are located in close proximity, reach-through currents will develop. As a result a chain of electrodes will be provided whereby every electrode element is at an individual potential level. Since the spacing in between two neighboring electrode elements represents an electric resistance the voltage distribution within the plurality of small electrode elements will exhibit a decreasing gradient. Thereby, the electrode elements being connected directly to a reference voltage will be at the highest positive or highest negative potential.

A segmented first electrode will provide the advantage that the electrical potential within the sidewalls can be shaped in an advantageous manner such that an improved drift of generated charge carriers within the sidewalls may be realized.

The segmentation of the first electrode may be realized by accomplishing various process steps during manufacturing the integrated circuit element. For instance the recesses can be formed by etching the semiconductor substrate in multiple steps. After each even step the sidewall doping is realized and after each odd step, a protective oxide layer is deposited at the corresponding sidewall surface portion.

According to a further embodiment of the invention the first electrode comprises a doping level, which is reduced from the backside surface towards the frontside surface. This may provide the advantage that a potential gradient within the first electrode may be realized such that the electrical potential within the sidewalls will be formed in a similar manner as described above when a segmented first electrode is employed.

The depth varying doping level of the first electrode may be realized by utilizing a vapor phase deposition (VPD) process. The VPD doping process can be optimized in such a way, that the doping linearly reduces from the backend surface towards the bottom of the recesses such that a continuous resistor chain is generated at the surface of sidewalls. Compared to processing a segmented first electrode the fabrication of the first electrode having a gradient of the doping strength is much more easy.

According to a further embodiment of the invention the plurality of recesses is arranged in a two dimensional array. This has the advantage that the described integrated circuit element may be used in order to build a flat X-ray detector having a spatial resolution, which is in particular high when (a) the recesses have a small cross sectional area being oriented parallel to the frontside respectively the backside surface of the semiconductor substrate and (b) the recesses are formed in close proximity with respect to each other.

Of course, since the spatial arrangement of the second electrodes respectively the collecting electrodes is connected to the plurality of recesses, also the plurality of second electrodes may be arranged in a two dimensional array. In this respect it has to be mentioned that there is no unambiguous assignment of one of the second electrodes representing a readout node to a specific scintillator column being formed within an individual recess. This has the effect that the pixel boundaries run through the scintillator material. Of course, this has the drawback that the separation of two neighboring pixels is not complete. However, the resulting reduction of the overall spatial resolution is so small that the corresponding X-ray sensitive detector still may have a much higher spatial resolution as compared to known X-ray detectors currently being used for X-ray imaging. This holds in particular if the recesses represent deep structures being formed in close distance to each other.

If a third electrode is used for separating neighboring second electrodes, the plurality of third electrodes may be formed preferably by means of a cross-structure representing an array, whereby within each pixel of this array one second electrode portion is formed. The use of at least one self contained cross-structure may provide the advantage that only a limited number of contacts to the third electrode have to be provided.

According to a further aspect of the invention there is provided an X-ray imaging detector having a spatial resolution, in particular an X-ray detector being used for medical applications. The provided X-ray detector comprises (a) a plurality of X-ray sensitive integrated circuit elements as described above and (b) a plurality of electronic circuit arrangements for connecting the first electrode and/or the second electrode.

It has to be mentioned that the electronic circuit arrangements may not only be used for providing the electrodes with appropriate biasing voltages. The electronic circuit arrangements may also be adapted to carry out a pre-amplification and/or a signal processing, when upon the detection of an X-ray photon within one of the scintillator columns a voltage drop at the second electrode representing the collecting electrode respectively the readout node of the X-ray sensitive circuit element is detected.

According to an embodiment of the invention the plurality of electronic circuit arrangements is formed on a separate chip being connected to the X-ray sensitive integrated circuit element. This may provide the advantage that on the frontside of the semiconductor substrate only photodiode related structures have to be processed. The connection between the integrated circuit element and the separate chip may be accomplished by means of known flip-chip bonding technologies or by means of providing through vias. Thereby, for realizing the X-ray detector a so-called system-in-package solution may be employed.

According to an alternative embodiment of the invention the electronic circuit arrangements are formed on the semiconductor substrate. Thereby the complete readout/amplification circuitry may be fabricated in the same wafer. In this case, the circuits would be realized in moderately doped p/n wells to prevent depletion extension there. It is particularly attractive if the size of the second electrode representing the readout electrode respectively the readout pixel is smaller than the cross-section of the recesses. This may provide the advantage that the remaining area can be used to facilitate the electronic circuit arrangements. Thereby, for realizing the X-ray detector a so-called system-on-chip solution may be employed.

According to a further aspect of the invention there is provided an X-ray imaging apparatus, in particular a medical X-ray imaging apparatus such as a computed tomography apparatus or a C-arm system. The X-ray imaging apparatus comprises an X-ray imaging detector as has been described above.

It has to be mentioned that the X-ray imaging detector described above may also be used for other purposes such as for material analysis, which may be carried out e.g. in baggage inspection systems.

According to a further aspect of the invention there is provided a method for fabricating an X-ray sensitive integrated circuit element, in particular for fabricating an X-ray sensitive integrated circuit element according to an embodiment as described above. The provided method comprises the steps of (a) providing a semiconductor substrate having a frontside surface and a backside surface, (b) forming a plurality of recesses within the semiconductor substrate from the backside surface towards the frontside surface, whereby two neighboring recesses are separated by a sidewall of the semiconductor substrate, (c) forming a plurality of first electrodes by means of a semiconductor doping procedure, whereby respectively one first electrode is formed at an inner surface of one recess, and (d) filling the plurality of recesses with scintillation material.

As has already been mentioned above in connection with the description of the X-ray sensitive integrated circuit element the second electrodes may be made from a semiconductor layer comprising a first conductivity type and the first electrodes may be made from a semiconductor layer comprising a second conductivity type. Further, the sidewalls formed from the semiconductor substrate may comprise the first conductivity type.

This aspect of the invention is based on the idea that an X-ray sensitive integrated circuit element according to any one of the embodiments described above may be fabricated by employing standard semiconductor processing technology, in particular by employing standard CMOS processing.

The recesses may be formed by means of so-called deep reactive ion etching (DRIE) or electrochemical wet etching. Thereby, recesses having a cross-section of approximately 50 μm×50 μm and a depth of approximately 500 μm may be generated. Of course, also recesses having other dimensions may be formed.

In particular, if the semiconductor substrate is made from pure silicon, which may be either intrinsic or lowly n-type doped, the doping procedure may be a so-called vapor phase doping, whereby e.g. boron is driven into the silicon sidewalls from surrounding ambient at high temperature in order to form shallow p-type sidewall junction. In this respect it has to be mentioned that during this operation the roughness of the surface of the silicon, which will be in particular big if DRIE is employed, will be at least partially removed because of a so-called silicon surface migration effect.

It has to be mentioned that the provided method is directed to a processing of a backside surface of a wafer substrate. Preferably before or after carrying out the backside processing the frontside of the corresponding wafer may be processed in an integrated circuit compatible way, whereby either only diode structures or complete CMOS circuits could be processed.

According to a further aspect of the invention the method further comprises the step of forming a passivation layer onto the plurality of first electrodes before filling the plurality of recesses with scintillation material. This may provide the advantage that a defined boundary between the semiconductor material and the scintillator material is realized such that no exchange of atoms in particular due to diffusion from the scintillator material into the semiconductor and vice versa occurs.

It has to be noted that embodiments of the invention have been described with reference to different subject matters. In particular, some embodiments have been described with reference to apparatus type claims whereas other embodiments have been described with reference to method type claims. However, a person skilled in the art will gather from the above and the following description that, unless other notified, in addition to any combination of features belonging to one type of subject matter also any combination between features relating to different subject matters, in particular between features of the apparatus type claims and features of the method type claims is considered to be disclosed with this application.

The aspects defined above and further aspects of the present invention are apparent from the examples of embodiment to be described hereinafter and are explained with reference to the examples of embodiment. The invention will be described in more detail hereinafter with reference to examples of embodiment but to which the invention is not limited.

### BRIEF DESCRIPTION OF THE DRAWINGS

FIG. 1 shows a simplified schematic representation of a computed tomography (CT) system, which is equipped with an X-ray detector comprising a plurality of X-ray sensitive integrated circuit elements according to an embodiment of the invention.

FIG. 2a shows a side view of a medical C-arm system, which is also is equipped with an X-ray detector comprising a plurality of X-ray sensitive integrated circuit elements according to an embodiment of the invention.

FIG. 2b shows a perspective view of the X-ray swing arm shown in FIG. 2a.

FIGS. 3a and 3b show cross sectional side views of an X-ray sensitive integrated circuit element according to an embodiment of the invention.

FIG. 4 shows an aerial top view of the X-ray sensitive integrated circuit element depicted in FIGS. 3a and 3b.

FIG. 5a shows a cross sectional side view of a portion of an X-ray imaging detector realized by means of a system-on-chip solution.

FIG. 5b shows a cross sectional side view of a portion of an X-ray imaging detector realized by means of a system-in-package solution.

FIG. 6 shows a cross sectional side view of an X-ray sensitive integrated circuit element having a segmented sidewall electrode.

### DETAILED DESCRIPTION

The illustration in the drawing is schematically. It is noted that in different figures, similar or identical elements are provided with reference signs, which are different from the corresponding reference signs only within the first digit.

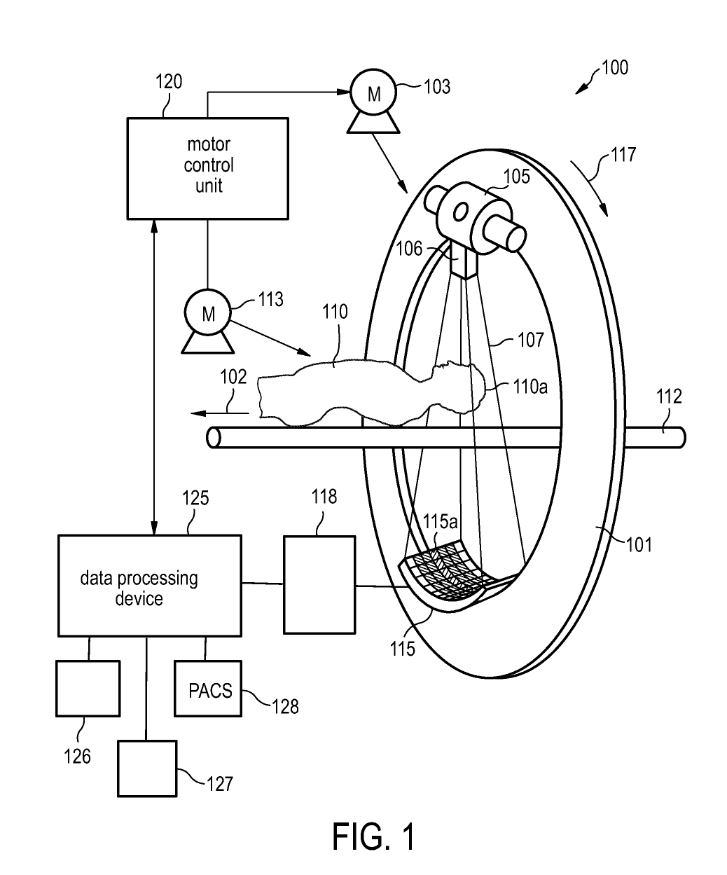

FIG. 1 shows a computer tomography (CT) apparatus 100, which is also called a CT scanner. The CT scanner 100 comprises a gantry 101, which is rotatable around a rotational axis 102. The gantry 101 is driven by means of a motor 103.

Reference numeral 105 designates a source of radiation such as an X-ray source, which emits polychromatic radiation 107. The CT scanner 100 further comprises an aperture system 106, which forms the X-radiation being emitted from the X-ray source 105 into a radiation beam 107. The spectral distribution of the radiation beam emitted from the radiation source 105 may further be changed by a filter element (not shown), which is arranged close to the aperture system 106.

The radiation beam 107, which may by a cone-shaped or a fan-shaped beam 107, is directed such that it penetrates a region of interest 110a. According to the embodiment described herewith, the region of interest is a head 110a of a patient 110.

The patient 110 is positioned on a table 112. The patient's head 110a is arranged in a central region of the gantry 101, which central region represents the examination region of the CT scanner 100. After penetrating the region of interest 110a the radiation beam 107 impinges onto a radiation detector 115. In order to be able to suppress X-radiation being scattered by the patient's head 110a and impinging onto the X-ray detector under an oblique angle there is provided a not depicted anti scatter grid. The anti scatter grid is preferably positioned directly in front of the detector 115.

The X-ray detector 115 is arranged on the gantry 101 opposite to the X-ray tube 105. The detector 115 comprises a plurality of detector elements 115a wherein each detector element 115a is capable of detecting X-ray photons, which have been passed through the head 110a of the patient 110. The detector elements 115a are realized by means of a plurality of X-ray sensitive integrated circuit elements, which will be described in detail below.

During scanning the region of interest 110a, the X-ray source 105, the aperture system 106 and the detector 115 are rotated together with the gantry 101 in a rotation direction indicated by an arrow 117. For rotation of the gantry 101, the motor 103 is connected to a motor control unit 120, which itself is connected to a data processing device 125. The data processing device 125 includes a reconstruction unit, which may be realized by means of hardware and/or by means of software. The reconstruction unit is adapted to reconstruct a three-dimensional (3D) image based on a plurality of 2D images obtained under various observation angles.

Furthermore, the data processing device 125 serves also as a control unit, which communicates with the motor control unit 120 in order to coordinate the movement of the gantry 101 with the movement of the table 112. A linear displacement of the table 112 is carried out by a motor 113, which is also connected to the motor control unit 120.

During operation of the CT scanner 100 the gantry 101 rotates and in the same time the table 112 is shifted linearly parallel to the rotational axis 102 such that a helical scan of the region of interest 110a is performed. It should be noted that it is also possible to perform a circular scan, where there is no displacement in a direction parallel to the rotational axis 102, but only the rotation of the gantry 101 around the rotational axis 102. Thereby, slices of the head 110a may be measured with high accuracy. A larger 3D representation of the patient's head may be obtained by sequentially moving the table 112 in discrete steps parallel to the rotational axis 102 after at least one half gantry rotation has been performed for each discrete table position.

The detector 115 is coupled to a pre-amplifier 118, which itself is coupled to the data processing device 125. The processing device 125 is capable, based on a plurality of different X-ray projection datasets, which have been acquired at different projection angles, to reconstruct a 3D representation of the patient's head 110a.

In order to observe the reconstructed 3D representation of the patient's head 110a a display 126 is provided, which is coupled to the data processing device 125. Additionally, arbitrary slices of a perspective view of the 3D representation may also be printed out by a printer 127, which is also coupled to the data processing device 125. Further, the data processing device 125 may also be coupled to a picture archiving and communications system 128 (PACS).

It should be noted that monitor 126, the printer 127 and/or other devices supplied within the CT scanner 100 might be arranged local to the computer tomography apparatus 100. Alternatively, these components may be remote from the CT scanner 100, such as elsewhere within an institution or hospital, or in an entirely different location linked to the CT scanner 100 via one or more configurable networks, such as the Internet, virtual private networks and so forth.

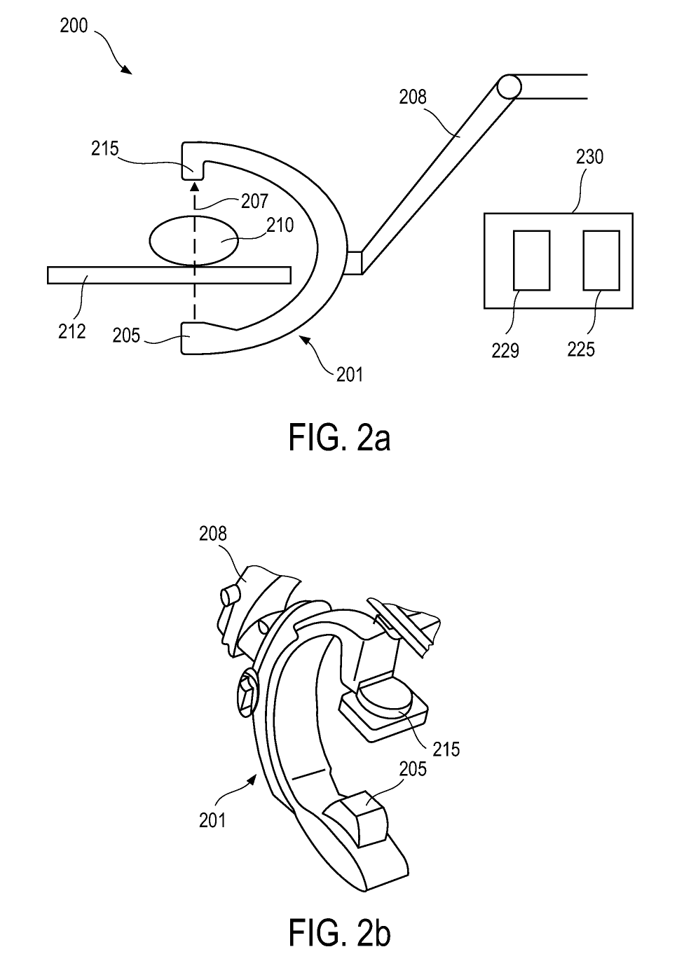

Referring to FIGS. 2a and 2b of the drawing, a medical X-ray imaging system 200 according to a further embodiment of the invention is a so called C-arm system. The C-arm system 200 comprises a swing arm scanning system 201 supported proximal a patient table 212 by a robotic arm 208. Housed within the swing C-arm 201, there is provided an X-ray tube 205 and an X-ray detector 215. The X-ray detector 215 is arranged and configured to detect X-rays 207, which have passed through a patient 210. Further, the X-ray detector 215 is adapted to generate an electrical signal representative of the intensity distribution thereof. By moving the swing arm 201, the X-ray tube 205 and the X-ray detector 215 can be placed at any desired location and orientation relative to the patient 210.

In order to be able to suppress X-radiation being scattered by the patient 210 and impinging onto the X-ray detector 215 under an oblique angle, there may be provided a not depicted anti scatter grid. The anti scatter grid may be positioned directly in front of the detector 215. The detector 215 comprises a plurality of X-ray sensitive integrated circuit elements, which will be described below in detail.

The C-arm system 200 further comprises a control unit 229 and a data processing device 225, which are both accommodated within a workstation or a personal computer 230. The control unit 229 is adapted to control the operation of the C-arm system 200.

It is pointed out that the mechanical precision of the C-arm system 200 may be good enough in order to allow for a 3D image reconstruction of the patient 210 based on a plurality of different projected two-dimensional images, which have been obtained by using the high precision C-arm system 200.

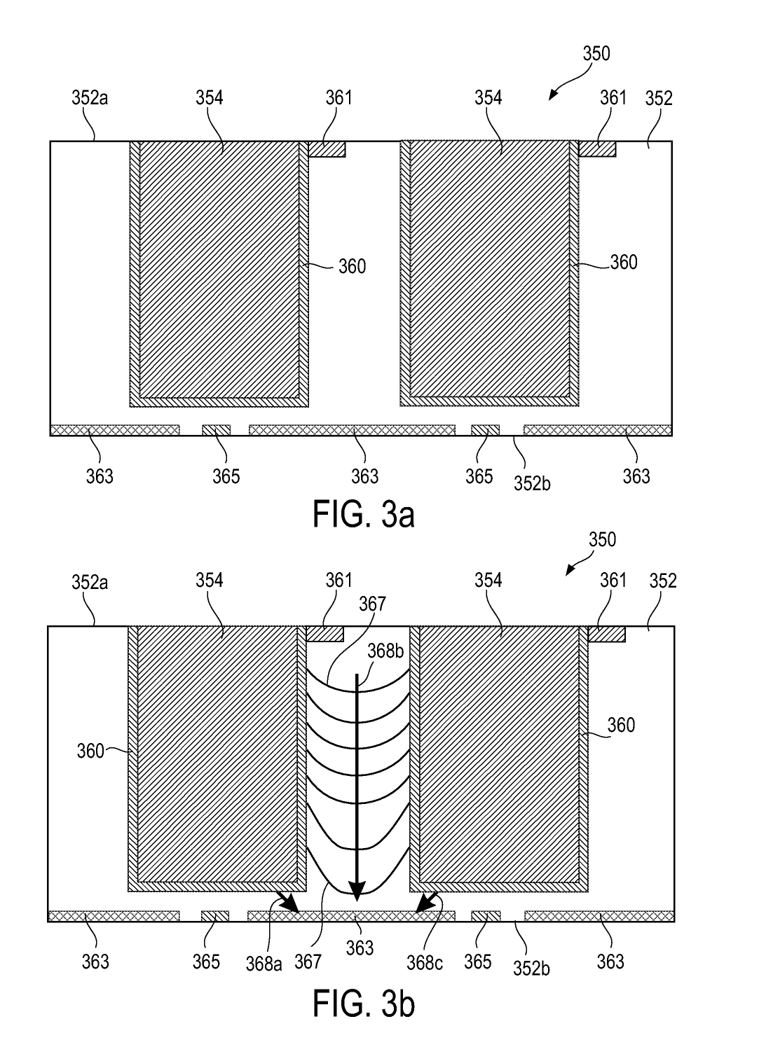

FIGS. 3a and 3b show cross sectional side views of an X-ray sensitive integrated circuit element 350 according to an embodiment of the invention. The integrated circuit element 350 is formed on a semiconductor substrate 352, which preferably is a high purity Silicon wafer crystal. The semiconductor substrate 352, which according to the embodiment described here is a lowly n-type doped material, comprises a backend surface 352a and a frontend surface 352b. Within the semiconductor substrate 352 there a formed a plurality of recesses 354. Within the portion of the integrated circuit element 350 depicted here, only two of the plurality of recesses can be seen. The represent a trench like opening which starting from the backend surface 352a extends towards the frontend surface 352b. Neighboring recesses 354 are separated by a sidewall of the semiconductor substrate 352.

On the inner surfaces of the trenches 354 there is provided a first electrode 360, which is formed by means of a p-doping procedure such as vapor phase doping. Thereby, according to the embodiment described here, boron is driven into the silicon sidewalls to form a shallow p-type junction 360. By means of a contact region 361 being formed at the backend surface 352a a negative voltage in the order of −10 V to −200 V can be applied to the first electrodes 360. According to the embodiment described here the contact region 361 is realized by means of a highly p-type doped region.

The frontend surface 352b of the substrate 352 is provided with second electrodes 363, which, according to the embodiment described here, are realized by a highly n-type doped region. The second electrodes 363 can be connected to a frontend circuitry for reading out and processing signals, which are detected at one of the second electrodes 363. The corresponding signal detection by means of the second electrode 363, which can also be designated as a collection electrode respectively a readout node of the integrated circuit element 350 will be described below.

The frontend surface 352b of the substrate 352 is further provided with third electrodes 365, which are arranged around the second electrode 363 in a plane oriented perpendicular to the plane of drawing. The third electrodes 365 are used in order to electrically separate neighboring second electrodes 363. According to the embodiment described here the third electrodes 365 are realized by a selective p-doping of the frontend surface 352b to a high p-doping level.

The recesses are filled with a scintillator material 354 such as for instance Cesiumiodide (CsI), which is doped with Thallium (Tl).

In order to provide for a defined boundary between the scintillator material 354 and the first electrodes 360 a thin passivation layer (not depicted) made preferably from SiO₂ may be formed in between the scintillator material 354 and the first electrodes 360.

When appropriately biasing the various electrodes 360, 363 and 365, an electrical potential between the neighboring first electrodes 360 on the one hand and a corresponding second electrode 363 being arranged in between the two neighboring first electrodes 360 will develop. This potential, which is indicated in FIG. 3b by the equipotential lines 367, may be generated for instance by applying a negative voltage of −50 V to the first electrodes 360 and ground voltages to the second electrodes 363 respectively the third electrode 365.

When an X-ray photon is absorbed within the scintillator blocks 354, light photons will be generated which penetrate the first electrodes 360 and induce in a known manner charge carriers predominately in the sidewall region in between two neighboring first electrodes 360. Thereby, the region in between the electrodes 360 and 363 represents the active region of a photodiode, which extends in between these electrodes 360 and 363. Because of the described arrangement of the electrodes 360, 363 and 365 in particular the sidewall region will be fully depleted from free charge carriers. The electron-hole pairs generated through photoelectric effect due to the light absorption in this region will be removed towards electrodes 360 and 363. The electrons will drift towards the electrode 363, while the holes are swept towards the electrode 360. In FIG. 3b the electron drift is indicated by the arrow 368b and by the arrows 368a and 368c.

It has to be mentioned that connecting the third electrode 365 to ground level will help to effectively separate the second electrodes 363 representing neighboring readout nodes of the integrated circuit element 350 such that also for most of the electrons, which are generated below the scintillator columns 354, a defined electron path 368a or 368c towards one of the second electrodes 363 is defined. This has the advantage that charge sharing between the neighboring electrodes 363 is reduced. Therefore, the third electrode 365 may also be denoted as a guard electrode.

The described design of the X-ray sensitive integrated circuit element 350 provide for various advantages:

1) The full depletion of the sidewalls decreases the effective capacitance, such that the associated noise and response time of a corresponding X-ray detector is very short.

2) The full depletion of the sidewalls further causes diminished diffusion current.

3) The comparatively small size of the readout electrode also contributes to a very low capacitance.

4) The shallow sidewall junctions with a thickness typically around 100 nm ensures a high light sensitivity due to a negligible absorption of light generated by the scintillator.

5) The X-ray sensitive detector can operate at relatively low reverse voltages.

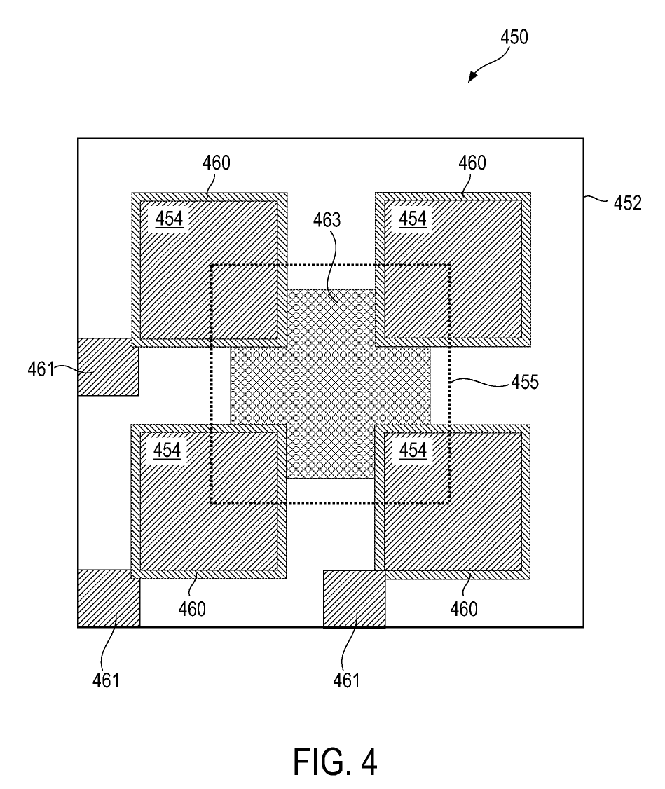

FIG. 4 shows an aerial top view of the X-ray sensitive integrated circuit element, which is now designated with reference numeral 450. The scintillator blocks 454, which are formed within the semiconductor substrate 452, are arranged within a two-dimensional array. On the front-side of the silicon substrate at a location corresponding to an area between four neighboring scintillator blocks 454, there is formed the second electrode 463 representing a readout node of the integrated circuit element 450. The X-ray sensitive active area of the integrated circuit element 450 corresponding to the depicted second electrode 463 is indicated by dashed lines 455. The first electrodes 460 are contacted by means of the contact regions 461, located on the back-side of the silicon substrate. For sake of clarity of the drawing the contact region being assigned to the first electrode 460 being arranged in the upper right position is omitted.

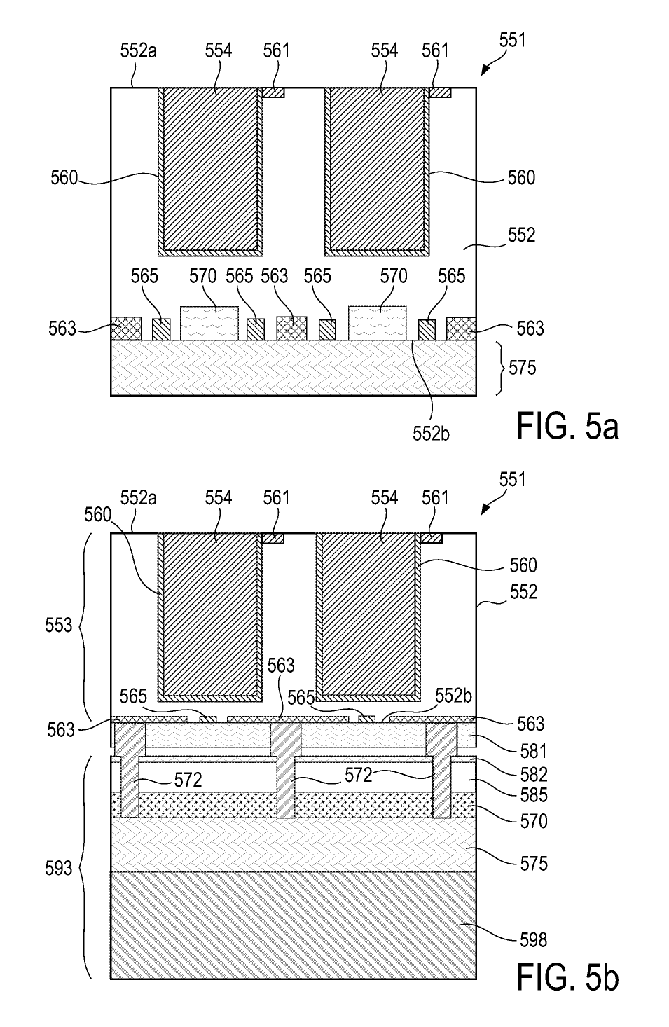

FIG. 5a shows a cross sectional side view of a portion of an X-ray imaging detector 551 according to an embodiment of the invention. The X-ray imaging detector 551 is based on the X-ray sensitive integrated circuit element 351, which has already been described in detail before with reference to FIG. 3a. Therefore, the elements known from FIG. 3a will not be described in detail once again.

The X-ray imaging detector 551 is realized by means of a so-called system-on-chip solution. Thereby, a CMOS frontend circuitry 570 is directly formed next to the highly p-type doped guard electrode 565 at the frontend surface 552b of the substrate 552. According to the embodiment described here the frontend circuitry 570 is not only used for providing the electrodes 560, 563 and 565 with appropriate biasing voltages. The electronic circuit 570 is also adapted to carry out a pre-amplification and/or a signal processing, when upon the detection of an X-ray photon within one of the scintillator columns 554 a voltage drop at the second electrode 563 is induced. The frontend surface 552b is covered with a CMOS backend layer 575, in where the metallic connections are arranged (not illustrated).

It has to be mentioned because of the presence of the frontend circuitry 570 the size of the second electrodes 563 representing the readout nodes is reduced as compared to the design shown in FIG. 3a.

FIG. 5b shows a cross sectional side view of a portion of an X-ray imaging detector 551 according to a further embodiment of the invention. The X-ray imaging detector 551 is also based on the X-ray sensitive integrated circuit element 351, which has already been described before with reference to FIG. 3a. The X-ray imaging detector 551 is realized by means of a so-called system-in-package solution. Thereby, components being related to the pn-photodiode are arranged on a first wafer 553 whereas components being related to the circuitry of the X-ray detector 551 are arranged on a second wafer 593.

Again, the design of the first wafer 553 corresponds to the circuit design, which has already been shown in FIG. 3a. However, in order to protect the frontend surface 552b, a first isolating layer is provided, which is preferably made of SiO₂.

The second wafer 593 comprises a glass substrate 598, on which there is formed a CMOS backend layer 575. On the CMOS backend layer 575 there is formed a layer comprising CMOS frontend circuitry 570. On the layer 570 there is formed a Silicon layer 585, which itself is covered by a second isolating layer 582. The second isolating layer 582 is preferably made of SiO₂.

Through connections 572 are provided in order to contact the CMOS frontend circuitry 570 with the electrodes 563 and 565. For sake of clarity of the drawing the through connections, which provide an electrical contact between the CMOS frontend circuitry 570 and the third electrodes 565 are omitted. The trough connections 572 can be made from metal or preferably from conductive poly silicon.

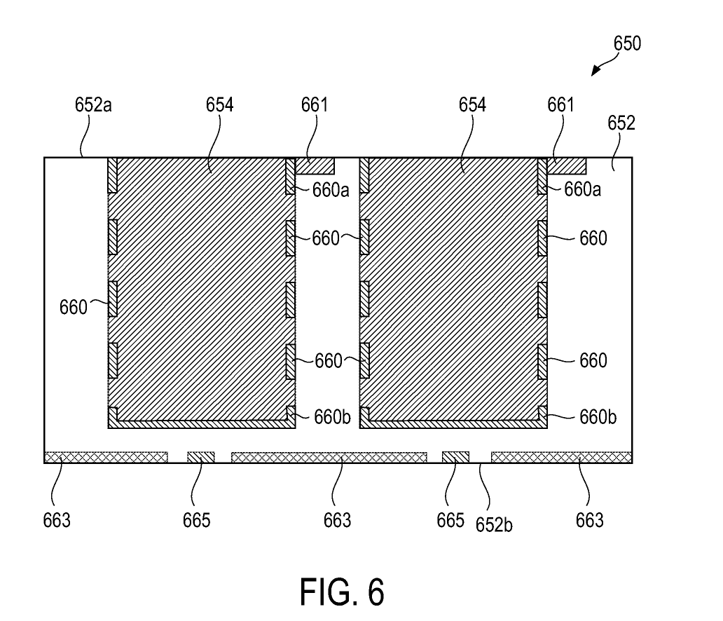

FIG. 6 shows a cross sectional side view of an X-ray sensitive integrated circuit element 650 having a segmented sidewall electrode 660 corresponding to the second electrode 360 shown in FIGS. 3a and 3b. The top segment 660a of the segmented sidewall electrode 660 is biased at the highest reverse voltage and the bottom segment 660b at lowest reverse voltage. Only these two segments are biased externally. The distribution of the voltage on the other segments is established by means of reach-through current in between neighboring segments.

The segmented electrode 660 may provide the advantage that the electrical potential within the sidewalls will be shaped in such a manner that an improved drift of generated electrons within the sidewalls may be realized. Thereby, the charge collection characteristics and response time of the X-ray sensitive circuit element 650 will be further reduced.

It should be noted that the term “comprising” does not exclude other elements or steps and the “a” or “an” does not exclude a plurality. Also elements described in association with different embodiments may be combined. It should also be noted that reference signs in the claims should not be construed as limiting the scope of the claims.

In order to recapitulate the above described embodiments of the present invention one can state:

This application describes an integrated circuit design and a method to fabricate the same for a high-efficiency, low-noise, position sensitive X-ray detection in particular for medical applications. The device 350 is based on deep recesses 354 filled with an X-ray sensitive scintillator material. A shallow first electrode 360 is formed on the surface of the substrate sidewalls separating two neighboring recesses 354. This sidewall electrode 360 in combination with particular frontside wafer electrode 363 structure results in a full depletion of the entire device 350 and a removal of signal charge towards the low capacitance readout electrode 363. The described integrated circuit element 350 ensures high and not depth dependent light collection efficiency.

### LIST OF REFERENCE SIGNS

100 medical X-ray imaging system/computed tomography apparatus
101 gantry
102 rotational axis
103 motor
105 X-ray source/X-ray tube
106 aperture system
107 radiation beam
110 object of interest/patient
110a region of interest/head of patient
112 table
113 motor
115 X-ray detector
115a detector elements
117 rotation direction
118 Pulse discriminator unit
120 motor control unit
125 data processing device (incl. reconstruction unit)
126 monitor
127 printer
128 Picture archiving and communication system (PACS)
200 medical X-ray imaging system/C-arm system
201 swing arm scanning system/C-arm
205 X-ray source/X-ray tube
207 X-ray
208 robotic arm
210 object of interest/patient
212 table
215 X-ray detector
225 data processing device
229 control unit
230 workstation/personal computer
350 X-ray sensitive integrated circuit element
352 semiconductor substrate (n-type doped)
352a backside surface/backend surface
352b frontside surface/frontend surface
354 recess, scintillator
360 first electrode (p-type doped)
361 contact region (p+ doped)
363 second electrode/collection electrode/readout node (n+ doped)
365 third electrode/guard electrode (p+ doped)
367 equipotential lines
368a electron drift path
368b electron drift path
368c electron drift path
450 X-ray sensitive integrated circuit element
452 semiconductor substrate (n-type doped)
454 recess, scintillator
455 active area of one pixel
460 first electrode (p-type doped)
461 contact region (p+ doped)
463 second electrode/collection electrode/readout node (n+ doped)
551 X-ray detector
552 semiconductor substrate (n-type doped)
552a backside surface/backend surface
552b frontside surface/frontend surface
553 first wafer
554 recess, scintillator
560 first electrode (p-type doped)
561 contact region (p+ doped)
563 second electrode/collection electrode/readout node (n+ doped)
565 third electrode/guard electrode (p+ doped)
570 CMOS frontend circuitry
572 through connection
575 CMOS backend
581 first isolating layer (SiO₂)
582 second isolating layer (SiO₂)
585 Silicon layer on isolator
593 second wafer
598 glass substrate
650 X-ray sensitive integrated circuit element
652 semiconductor substrate (n-type doped)
652a backside surface/backend surface
652b frontside surface/frontend surface
654 recess, scintillator
660 segmented first electrode (p-type doped)
660a top segment
660b bottom segment
661 contact region (p+ doped)
663 second electrode/collection electrode/readout node (n+ doped)
665 third electrode/guard electrode (p+ doped)

1. An X-ray sensitive integrated circuit element for an X-ray imaging detector, in particular for an X-ray imaging detector being used for medical applications, the X-ray sensitive integrated circuit element (350) comprising
a semiconductor substrate (352) having a frontside surface (352b) and a
backside surface (352a),
a plurality of recesses (354) being formed within the semiconductor substrate (352) from the backside surface (352a) towards the frontside (352b) surface, whereby two neighboring recesses (354) are separated by a sidewall of the semiconductor substrate (352),
a plurality of first electrodes (360), whereby respectively one first electrode (360) is formed at an inner surface of one recess (354),
an X-ray sensitive scintillator material (354) being filled within the plurality of recesses (354), and
a plurality of second electrodes (363) being formed at the frontside surface (352b), whereby respectively one second electrode (363) faces one sidewall.

2. An X-ray sensitive integrated circuit element according to claim 1, whereby
the recesses (354) are deep structures having a depth which is larger than the width.

3. An X-ray sensitive integrated circuit element according to claim 1, further comprising
a plurality of third electrodes (365) being formed at the frontside surface (352b), whereby respectively one third electrode (365) is arranged in between two neighboring second electrodes (363).

4. An X-ray sensitive integrated circuit element according to claim 1, whereby
the first electrodes (360) have a thickness of less than 1 μm, preferably less than 0.5 μm.

5. An X-ray sensitive integrated circuit element according to claim 1, further comprising
a light reflecting layer, which is provided at a surface of the scintillator (354) formed at the back surface (352a) of the semiconductor substrate (352).

6. An X-ray sensitive integrated circuit element according to claim 1, whereby
the semiconductor substrate (352) is at least a part of a semiconductor wafer, which preferably is made from Silicon.

7. An X-ray sensitive integrated circuit element according to claim 1, further comprising
a passivation layer being formed in between the scintillator material (354) and the first electrode (360).

8. An X-ray sensitive integrated circuit element according to claim 1, whereby
the semiconductor substrate (352) is an intrinsic or a lowly n-type doped semiconductor material,
the first electrode (360) is formed as a p-type doped region within the semiconductor substrate (352), and
the second electrode (363) is formed as a n-type doped region within the semiconductor substrate (352).

9. An X-ray sensitive integrated circuit element according to claim 1, whereby
the first electrode (360) is contacted from the backside surface (352a) of the semiconductor substrate (352).

10. An X-ray sensitive integrated circuit element according to claim 1, whereby
the first electrode in contacted from the frontside surface of the semiconductor substrate.

11. An X-ray sensitive integrated circuit element according to claim 1, whereby
the first electrode (660) is segmented in depth.

12. An X-ray sensitive integrated circuit element according to claim 1, whereby
the first electrode (360) comprises a doping level, which is reduced from the backside surface (352a) towards the frontside surface (352b).

13. An X-ray sensitive integrated circuit element according to claim 1, whereby
the plurality of recesses (454) is arranged in a two dimensional array.

14. An X-ray imaging detector having a spatial resolution, in particular an X-ray detector being used for medical applications, the X-ray detector comprising
a plurality of X-ray sensitive integrated circuit elements (350) as set forth in claim 1 and
a plurality of electronic circuit arrangements (570) for connecting the first electrode (560) and/or the second electrode (563).

15. An X-ray imaging detector according to claim 14, whereby
the plurality of electronic circuit arrangements (570) is formed on a separate chip (593) being connected to the X-ray sensitive integrated circuit element (553).

16. An X-ray imaging detector according to claim 14, whereby
the electronic circuit arrangements (570) are formed on the semiconductor substrate (552).

17. An X-ray imaging apparatus, in particular a medical X-ray imaging apparatus such as a computed tomography apparatus (100) or a C-arm system (200), the X-ray imaging apparatus comprising
an X-ray imaging detector (551) as set forth in claim 14.

18. A method for fabricating an X-ray sensitive integrated circuit element (350), in particular an X-ray sensitive integrated circuit element (350) as set forth in claim 1, the method comprising the steps of
providing a semiconductor substrate (352) having a frontside surface (352b) and a backside surface (352a),
forming a plurality of recesses (354) within the semiconductor substrate (352) from the backside surface (352a) towards the frontside surface (352b), whereby two neighboring recesses (354) are separated by a sidewall of the semiconductor substrate (352),
forming a plurality of first electrodes (360) by means of a semiconductor doping procedure, whereby respectively one first electrode (360) is formed at an inner surface of one recess (354), and
filling the plurality of recesses (354) with scintillation material.

19. A method according to claim 16, further comprising the step of forming a passivation layer onto the plurality of first electrodes (360) before filling the plurality of recesses (354) with scintillation material.
